(19) United States
(12) Patent Application Publication
(10) Pub. No.: US 2025/0157535 A1
(43) Pub. Date: May 15, 2025

(54) METHOD FOR OPERATING MEMORY APPARATUS, MEMORY APPARATUS, DEVICE, AND STORAGE MEDIUM

(71) Applicant: XIAMEN INDUSTRIAL TECHNOLOGY RESEARCH INSTITUTE CO., LTD., Xiamen (CN)

(72) Inventors: Yuhuang CHEN, Xiamen (CN); Meidong LIU, Xiamen (CN); Juilung CHEN, Xiamen (CN); Tianhui HUANG, Xiamen (CN); Taiwei CHIU, Xiamen (CN)

(73) Assignee: XIAMEN INDUSTRIAL TECHNOLOGY RESEARCH INSTITUTE CO., LTD., Xiamen (CN)

(21) Appl. No.: 19/023,486

(22) Filed: Jan. 16, 2025

Related U.S. Application Data
(63) Continuation of application No. PCT/CN2024/107282, filed on Jul. 24, 2024.

(30) Foreign Application Priority Data
Sep. 1, 2023 (CN) 202311125480.X

(51) Int. Cl. G11C 13/00; H10B 63/00

(52) U.S. Cl. CPC G11C 13/003; G11C 13/0069; H10B 63/30; G11C 2013/0083

(57) ABSTRACT

A method for operating a memory apparatus, a memory apparatus, a device, and a storage medium are provided. The method includes: providing a semiconductor device including a substrate, a deep N-well region disposed in the substrate, a P-well region disposed in the deep N-well region, and a plurality of transistor structures disposed in the P-well region, where each of the transistor structures includes a gate, a source and a drain; and applying a first voltage to a port of the gate, a second voltage to a port of the deep N-well region, and a third voltage to a port of the P-well region. When a first operation is performed, the first voltage is equal to 0, the second voltage is a positive voltage, and the third voltage is a negative voltage; when a second operation is performed, the first, second and third voltages are positive voltages.

### CROSS REFERENCE TO THE RELATED APPLICATIONS

The present application is a continuation application of International Application No. PCT/CN2024/107282, filed on Jul. 24, 2024, which is based upon and claims priority to Chinese patent application No. 202311125480.X, filed on Sep. 1, 2023, the entire contents of which are incorporated herein by reference.

### TECHNICAL FIELD

The present disclosure relates to the technical field of semiconductors, and in particular to a method for operating a memory apparatus, a memory apparatus, a device, and a storage medium.

### BACKGROUND

A resistive random access memory (RRAM) is a non-volatile memory, and the RRAM can store data by means of changes in its resistance state.

The purpose of reset is to change the resistance state of the RRAM from a low resistance state (LRS) to a high resistance state (HRS). Due to low resistance of the RRAM, the IR drop effect is obvious, and most voltage is divided after current flows through MOS transistors, resulting in low current flowing through the RRAM and making it difficult to reset.

As the feature size of process nodes continues to decrease, the distance between a source end and a drain end of a device is increasingly short. However, in an RRAM circuit, the operating voltage cannot be reduced due to the influence of RRAM characteristics, resulting in an enhanced electric field between the source end and the drain end, drain-induced barrier lowering (DIBL) and subsequent bulk punch-through.

Therefore, it is necessary to propose a solution to solve those problems in the above different situations.

### SUMMARY

The present disclosure provides a method for operating a memory apparatus, a memory apparatus, a device, and a storage medium to at least solve the above technical problems in the related art.

According to a first aspect of the present disclosure, a method for operating a memory apparatus is provided, which includes:
providing a semiconductor device, where the semiconductor device includes a substrate, a deep N-well region disposed in the substrate, a P-well region disposed in the deep N-well region, and a plurality of transistor structures disposed in the P-well region; where each of the plurality of transistor structures includes a gate, as well as a source and a drain disposed on two sides of the gate respectively; and
applying a first voltage to a port of the gate, applying a second voltage to a port of the deep N-well region, and applying a third voltage to a port of the P-well region;
when a first operation is performed, the first voltage is equal to 0, the second voltage is a positive voltage, and the third voltage is a negative voltage;
when a second operation is performed, the first voltage is a positive voltage, the second voltage is a positive voltage, and the third voltage is a positive voltage.

In one implementation, the method may further include: when a third operation is performed, the first voltage is equal to 0, the second voltage is a positive voltage, and the third voltage is a positive voltage.

In one implementation, the second operation may be a forming operation, and the third operation may be a reset operation.

In one implementation, the semiconductor device may further include: a resistive unit, a first end of the resistive unit being connected to the drain through a first connecting layer; a bit line connected to a second end of the resistive unit; a source line connected to the source through a second connecting layer; and a word line connected to the gate;

the step of applying the first voltage to the port of the gate may include: applying the first voltage to the port of the gate through the word line; and
the method may further include:
applying a fourth voltage to the drain through the bit line; wherein the fourth voltage is a positive voltage; and
grounding the source through the source line.

In one implementation, when the first operation is performed, the third voltage may be greater than or equal to −1 V and less than 0 V; and
when the second operation or the third operation is performed, the third voltage may be greater than 0 V and less than or equal to 1 V.

According to a second aspect of the present disclosure, a memory apparatus is provided, which includes:
a semiconductor device; where the semiconductor device includes a substrate, a deep N-well region disposed in the substrate, a P-well region disposed in the deep N-well region, and a plurality of transistor structures disposed in the P-well region; where each of the plurality of transistor structures includes a gate, as well as a source and a drain disposed on two sides of the gate respectively; and
a voltage module, configured to apply a first voltage to a port of the gate, apply a second voltage to a port of the deep N-well region, and apply a third voltage to a port of the P-well region;
when a first operation is performed, the first voltage is equal to 0, the second voltage is a positive voltage, and the third voltage is a negative voltage;
when a second operation is performed, the first voltage is a positive voltage, the second voltage is a positive voltage, and the third voltage is a positive voltage.

In one implementation, when a third operation is performed, the first voltage may be equal to 0, the second voltage may be a positive voltage, and the third voltage may be a positive voltage.

In one implementation, the second operation may be a forming operation, and the third operation may be a reset operation.

In one implementation, the semiconductor device may further include: a resistive unit, a first end of the resistive unit being connected to the drain through a first connecting layer; a bit line connected to a second end of the resistive unit; a source line connected to the source through a second connecting layer; and a word line connected to the gate;
the voltage module may further be configured to apply the first voltage to the port of the gate through the word line; and
the voltage module may further be configured to:
apply a fourth voltage to the drain through the bit line; where the fourth voltage may be a positive voltage; and
ground the source through the source line.

In one implementation, when the first operation is performed, the third voltage may be greater than or equal to −1 V and less than 0 V; and
when the second operation or the third operation is performed, the third voltage may be greater than 0 V and less than or equal to 1 V.

According to a third aspect of the present disclosure, an electronic device is provided, which includes:
at least one processor; and
a memory in communication connection with the at least one processor;
where the memory stores instructions executable by the at least one processor, and the instructions are executed by the at least one processor to cause the at least one processor to execute the method described in the present disclosure.

According to a fourth aspect of the present disclosure, a non-transitory computer-readable storage medium storing computer instructions is provided, and the computer instructions are executed by a computer to cause the computer to perform the method described in the present disclosure.

According to the method for operating a memory apparatus, the memory apparatus, the device, and the storage medium of the present disclosure, by forming the deep N-well region in the substrate to isolate the substrate from the P-well region, the voltage in the P-well region can be controlled separately. By applying a negative pressure to the P-well region, the transistor structure is not easily turned on, thereby effectively reducing leakage current caused by punch-through. Meanwhile, during normal forming, a positive voltage is applied to the P-well region, so that the transistor structure is easily turned on, thereby reducing the threshold voltage for transistors and increasing the turn-on current (Idsat).

It should be understood that the content described in this section is not intended to identify critical or important features of the embodiments of the present disclosure, and is not used to limit the scope of the present disclosure either. Other features of the present disclosure will be easily understood through the following description.

### BRIEF DESCRIPTION OF THE DRAWINGS

By reading the following detailed description with reference to the accompanying drawings, the above and other objectives, features and advantages of the exemplary embodiments of the present disclosure will become easier to understand. In the drawings, several embodiments of the present disclosure are shown in an exemplary and non-limiting manner.

In the drawings, the same or corresponding reference numerals denote the same or corresponding parts.

FIG. 1 is a circuit diagram of a semiconductor device in the related art.

FIG. 2 is a circuit diagram of a transistor structure in the related art.

FIG. 3A and FIG. 3B are diagrams showing drain current characteristics of a transistor structure under a bulk punch-through effect.

FIG. 4 is a flowchart of a method for operating a memory apparatus provided in an embodiment of the present disclosure.

FIG. 5 is a structural diagram of a semiconductor device provided in an embodiment of the present disclosure.

FIG. 6 is a circuit diagram of a transistor structure provided in an embodiment of the present disclosure.

FIG. 7 is a diagram showing circuit simulation results of performing a first operation.

FIG. 8 is a diagram showing circuit simulation results of performing a second operation.

FIG. 9 is a structural diagram of an electronic device according to an embodiment of the present disclosure.

### DETAILED DESCRIPTION OF THE EMBODIMENTS

In order to make the objectives, features, and advantages of the present disclosure more apparent and easier to understand, the technical solutions in the embodiments of the present disclosure will be clearly and completely described below with reference to the accompanying drawings therein. Apparently, the described embodiments are merely a part rather than all of the embodiments of the present disclosure. All other embodiments obtained by those skilled in the art based on the embodiments of the present disclosure without any creative efforts shall fall within the protection scope of the present disclosure.

FIG. 1 is a circuit diagram of a semiconductor device in the related art. In the related art, the transistor structure used in an RRAM is a 0.9V device, and high voltage needs to be applied to BL0 during operation, resulting in drain-induced barrier lowering and an increase in the probability of bulk punch-through in the entire storage chip. In addition, insufficient excitation occurs due to the influence of voltage drop.

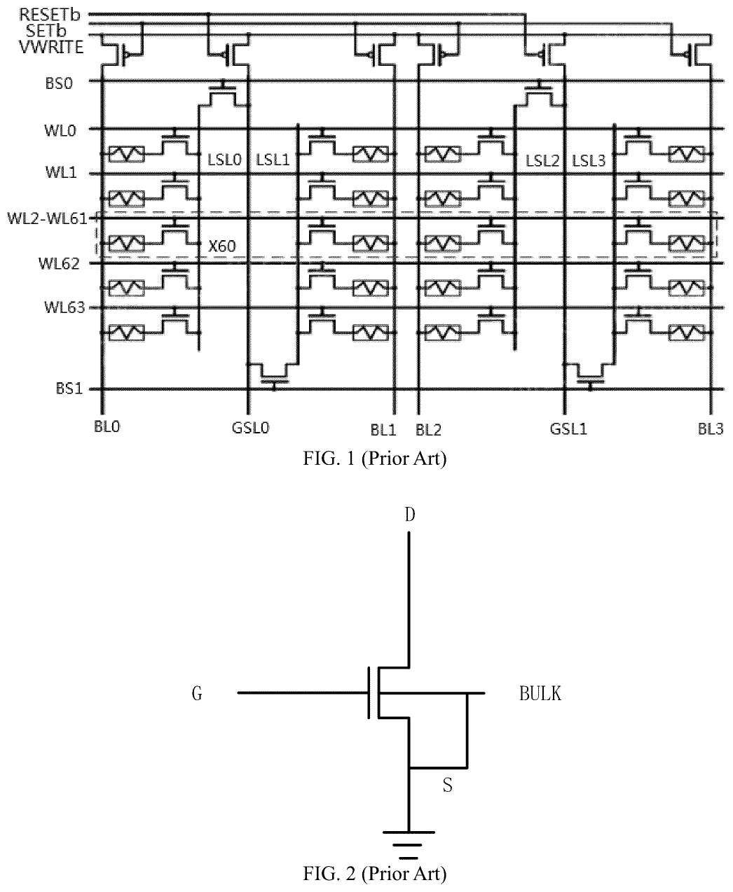

FIG. 2 is a circuit diagram of a transistor structure in the related art. Since the transistor structure in the related art does not have a deep N-well region, the potential of a P-well region (that is, a BULK terminal in FIG. 2) cannot be controlled separately. Therefore, the semiconductor device in the related art is more prone to drain-induced barrier lowering and bulk punch-through effects.

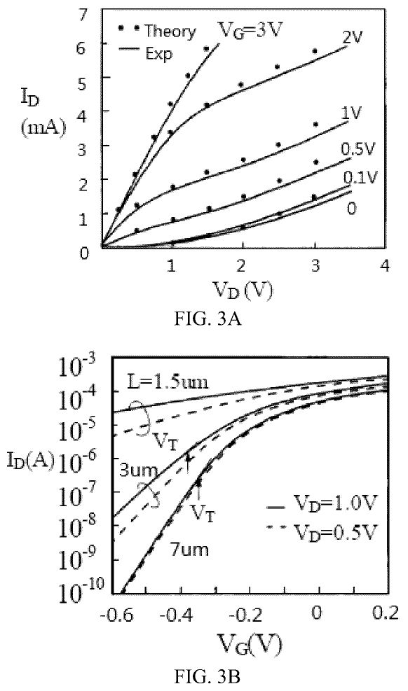

FIG. 3A and FIG. 3B are diagrams showing drain current characteristics of a transistor structure under a bulk punch-through effect. FIG. 3A illustrates an example of a severe bulk punch-through effect in a region above a threshold. For a drain voltage range shown in FIG. 3A, the device operates under punch-through conditions. FIG. 3B illustrates a drain-induced barrier lowering effect and a bulk punch-through effect of subthreshold current for devices with different channel lengths. The device with a channel length of 7 μm exhibits long channel characteristics, that is, the subthreshold current is independent of drain voltage. For the device with a channel length of 1.5 μm, the long channel characteristics completely disappear, the subthreshold swing is worse, and the device cannot be turned off. Therefore, the drain-induced barrier lowering and bulk punch-through of the semiconductor device affect the performance of the device, so that the device cannot operate normally.

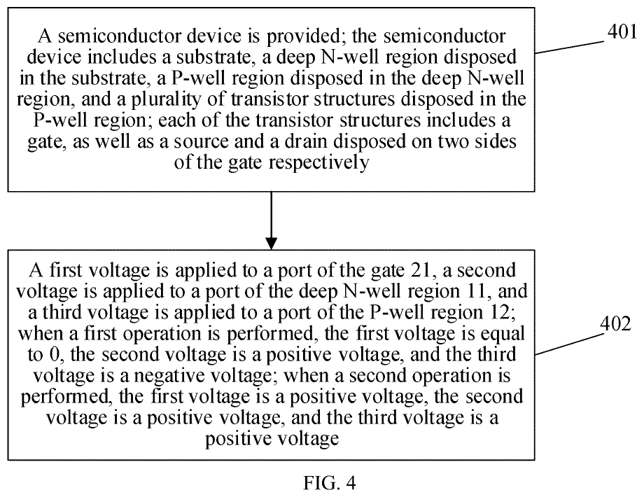

The following will introduce a method for operating a memory apparatus provided in an embodiment of the present disclosure. FIG. 4 is a flowchart of a method for operating a memory apparatus provided in an embodiment of the present disclosure. The following will provide a detailed explanation with reference to steps 401 and 402 in FIG. 4.

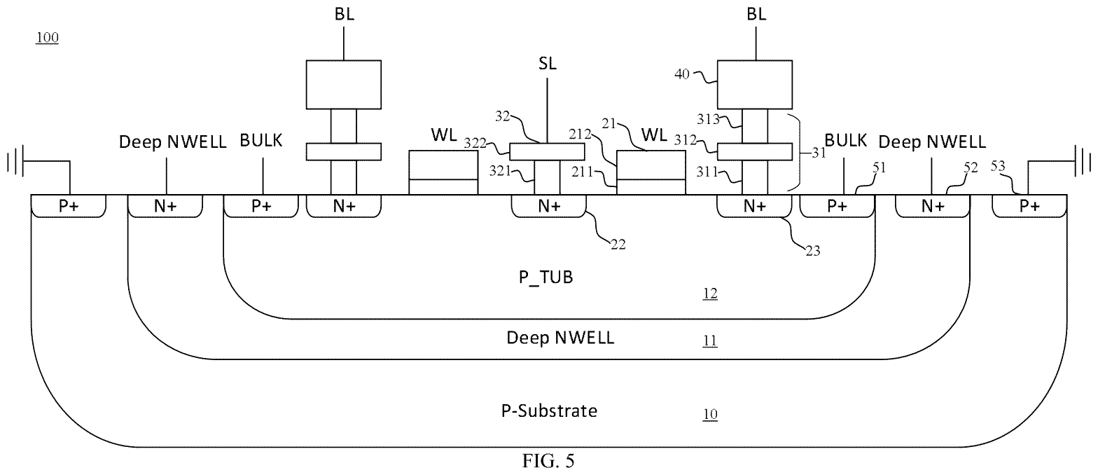

Step 401, with reference to FIG. 5, a semiconductor device 100 is provided; the semiconductor device 100 includes a substrate 10, a deep N-well region 11 disposed in the substrate 10, a P-well region 12 disposed in the deep N-well region 11, and a plurality of transistor structures disposed in the P-well region 12; each of the transistor structures includes a gate 21, as well as a source 22 and a drain 23 disposed on two sides of the gate 21 respectively.

In some embodiments, the substrate 10 may be an elemental semiconductor material substrate (such as a silicon substrate, a germanium substrate, or the like), a composite semiconductor material substrate (such as a germanium-silicon substrate or the like), a silicon on insulator (SOI) substrate, a germanium on insulator (GOI) substrate, or the like.

Then, the deep N-well region 11 is formed in the substrate 10, the P-well region 12 is formed in the deep N-well region 11, and the plurality of transistor structures are formed in the P-well region 12. The deep N-well region 11 isolates the substrate 10 from the P-well region 12 to control voltage in the P-well region separately.

In an embodiment, the transistor structure includes the gate 21, and the gate 21 includes a gate dielectric layer 211 disposed on the P-well region 12 and a gate conductive layer 212 disposed on the gate dielectric layer 211. The material of the gate dielectric layer 211 includes, but is not limited to oxides, such as silicon oxide. The material of the gate conductive layer 212 may be any material with good conductivity, such as any of titanium (Ti), titanium nitride (TiN), tungsten nitride (WN), tungsten (W), cobalt (Co), platinum (Pt), palladium (Pd), ruthenium (Ru), or copper (Cu).

The transistor structure further includes the source 22 and the drain 23 which are disposed on two sides of the gate 21. Specifically, as shown in FIG. 5, the source 22 and the drain 23 are disposed in the P-well region 12. In the embodiments of the present disclosure, the source 22 and the drain 23 are N-type doping regions.

In an embodiment, the semiconductor device 100 further includes: a resistive unit (also called resistive switching unit) 40, a first end of the resistive unit 40 being connected to the drain 23 through a first connecting layer 31; a bit line BL connected to a second end of the resistive unit 40; a source line SL connected to the source 22 through a second connecting layer 32; and a word line WL connected to the gate 21.

Specifically, the first connecting layer 31 includes a first connecting line 311, a first conductive layer 312, and a second connecting line 313 arranged sequentially from bottom to top.

In an embodiment, the materials of the first connecting line 311 and the second connecting line 313 and the material of the first conductive layer 312 may include suitable conductor materials such as metal materials, barrier metal materials, or combinations thereof. The materials of the first connecting line 311 and the second connecting line 313 may be the same as or different from the material of the first conductive layer 312.

In an embodiment, the materials of the bit line BL, the source line SL, and the word line WL include tungsten (W), copper (Cu), titanium (Ti), tantalum (Ta), titanium nitride (TiN), tantalum nitride (TaN), metal silicide, metal alloy, or any combination thereof.

In an embodiment, the semiconductor device 100 further includes: a first doping region 51 disposed in the P-well region 12, a second doping region 52 disposed in the deep N-well region 11, and a third doping region 53 disposed in the substrate 10. The first doping region 51 is used for receiving voltage applied to the P-well region 12, the second doping region 52 is used for receiving voltage applied to the deep N-well region 11, and the third doping region 53 is used for receiving voltage applied to the substrate 10. The first doping region 51 is a P-type doping region, the second doping region 52 is an N-type doping region, and the third doping region 53 is a P-type doping region.

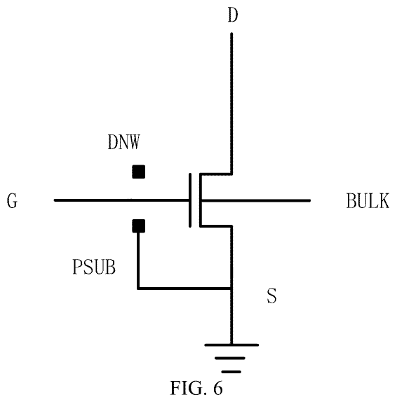

FIG. 6 is a circuit diagram of a transistor structure provided in an embodiment of the present disclosure. As shown in FIG. 6, the transistor structure in the embodiments of the present disclosure has an additional deep N-well region (DNW) compared with the transistor structure in the related art, so potentials at deep N-well region (DNW) and P-well region (BULK) terminals can be controlled separately.

Step 402, a first voltage is applied to a port of the gate 21, a second voltage is applied to a port of the deep N-well region 11, and a third voltage is applied to a port of the P-well region 12; when a first operation is performed, the first voltage is equal to 0, the second voltage is a positive voltage, and the third voltage is a negative voltage; when a second operation is performed, the first voltage is a positive voltage, the second voltage is a positive voltage, and the third voltage is a positive voltage.

In the embodiments of the present disclosure, by forming the deep N-well region in the substrate to isolate the substrate from the P-well region, the voltage in the P-well region can be controlled separately. By applying a negative pressure to the P-well region, the transistor structure is not easily turned on, thereby effectively reducing leakage current caused by punch-through. Meanwhile, during normal forming, a positive voltage is applied to the P-well region, so that the transistor structure is easily turned on, thereby reducing the threshold voltage for transistors and increasing the turn-on current (Idsat).

In an embodiment, the method further includes: when a third operation is performed, the first voltage is equal to 0, the second voltage is a positive voltage, and the third voltage is a positive voltage.

In the embodiments of the present disclosure, by giving a positive voltage to the P-well region, a reset circuit is turned on from the P-well region through a PN junction, without voltage division by transistors, but with easy operation and a high success rate. Additionally, all RRAMs share one P-well region to achieve chip-based reset, thereby reducing operation time.

In an embodiment, the second operation is an initialization operation (also called a forming operation), and the third operation is a reset operation.

In an embodiment, the applying the first voltage to the port of the gate 21 includes: applying the first voltage to the port of the gate 21 through the word line WL;

The method further includes: applying a fourth voltage to the drain 23 through the bit line BL; and grounding the source 22 through the source line SL. The fourth voltage is a positive voltage.

As shown in FIG. 6, a port (PSUB) of the substrate 10 is also grounded.

For an MOS device, the substrate and the gate have the same function(s). Since the positive voltage is applied to the gate to turn on the transistor, the negative voltage of the substrate can counteract this effect. Therefore, for the gate, the negative voltage of the substrate increases a threshold voltage, making it more difficult to turn on the transistor. In the embodiment of the present disclosure, the P-well region is equivalent to the substrate.

The first operation is further explained in conjunction with formula (1) below:

$${V}_{th} = {V}_{th 0} + γ ( \sqrt{\vert 2 {φ}_{F} + {V}_{S B} \vert} - \sqrt{\vert 2 {φ}_{F} \vert} ) \qquad ( 1 )$$

In formula (1), Vₜₕ represents a threshold voltage, Vₜₕ₀ represents a threshold voltage under zero bias conditions, y represents a swing coefficient, φ_{F} represents a surface barrier height, V_{SB} represents a reverse voltage between the source/drain and the substrate, namely, V_{SB}=Vₛ−V_{B}; generally V_{B}=V_{S}, but when the voltage of the substrate is negative, namely, when V_{B} drops, V_{SB} increases, thereby increasing the threshold voltage Vₜₕ.

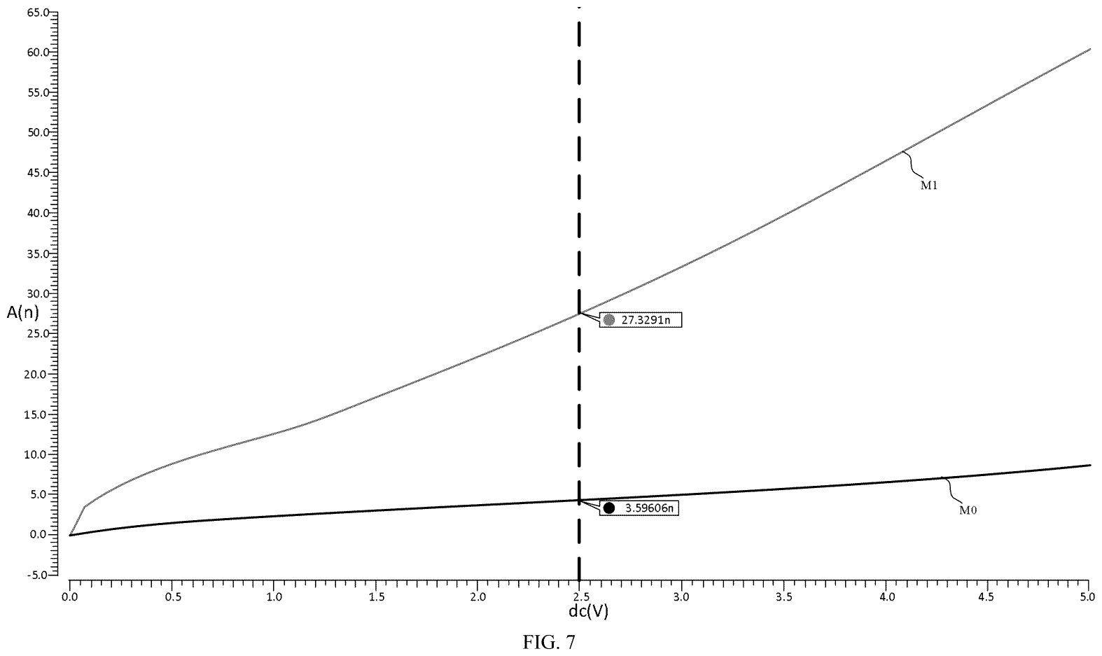

FIG. 7 is a diagram showing circuit simulation results of performing a first operation.

In this embodiment, when the semiconductor device is turned off, the first voltage Vgs applied to the port of the gate is 0 V, the second voltage Vdnw applied to the port of the deep N-well region is 0.9 V, and the third voltage Vbulk applied to the port of the P-well region is −0.5 V. When 1024 NMOSs are connected in series in the RRAM array and a width-to-length ratio of an NMOS is 270 μm/270 μm, simulation results are shown in FIG. 7.

As shown in FIG. 7, a curve M0 is a simulation curve of the transistor structure in the embodiments of the present disclosure, and a curve M1 is a simulation curve of the transistor structure in the related art. When drain voltage Vd=2.5 V is selected, the leakage current of M0 is 3.596 nA, and the leakage current of M1 is 27.3291 nA. It can be seen that after the deep N-well region is added, the transistor structure is not easily turned on by applying the negative voltage to the P-well region; and when the device is turned off, the turn-off current Ioff is significantly reduced, thereby achieving the effect of reducing punch-through.

The second operation is further explained in conjunction with formula (2) below:

$${I}_{d} = {μ}_{n} {C}_{o x} \frac{W}{L} [ ( {V}_{G S} - {V}_{th} ) {V}_{D S} - \frac{1}{2} {V}_{DS}^{2} ] \qquad ( 2 )$$

In formula (2), I_{d} represents drain current, w/L represents a width-to-length ratio of an MOS transistor, μₙ represents electron mobility, Cₒₓ represents capacitance of an oxide layer, V_{GS} represents gate source voltage, Vₜₕ represents a threshold voltage, and V_{DS} represents a drain source voltage.

Based on formula (1) above, in this embodiment, when a positive voltage is applied to the substrate, namely, Vbulk is a positive voltage, the threshold voltage Vₜₕ in formula (1) decreases. When Vₜₕ decreases, it is substituted into formula (2) to obtain increasing drain current I_{d}.

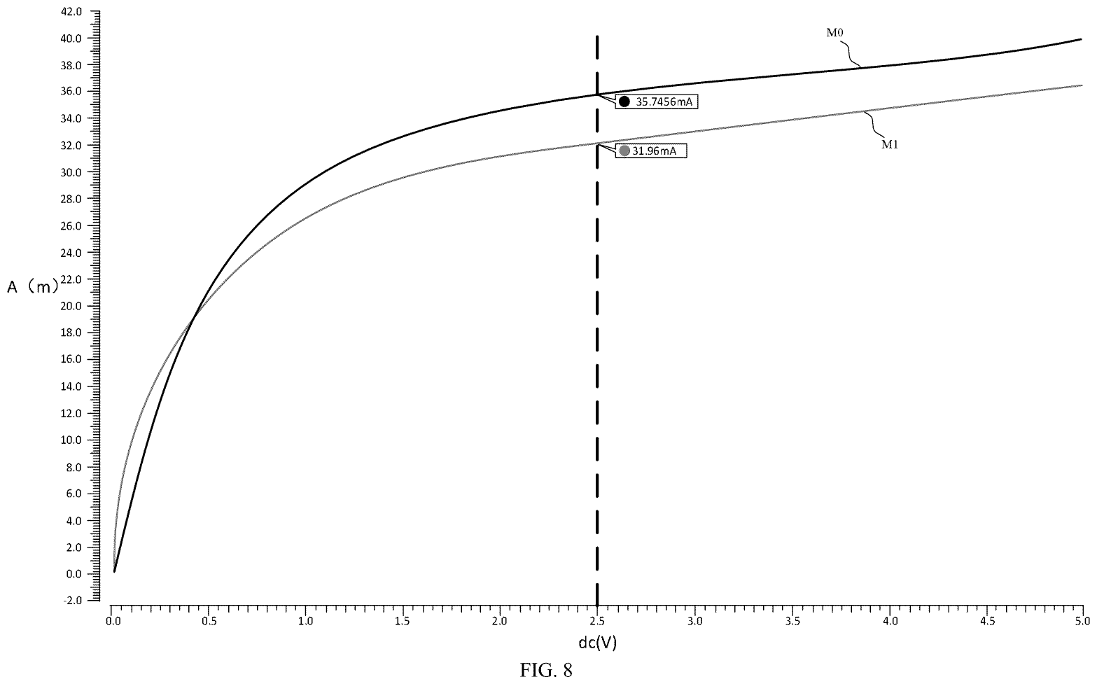

FIG. 8 is a diagram showing circuit simulation results of performing a second operation.

When the semiconductor device is turned on, the first voltage Vgs applied to the port of the gate is 1 V, the second voltage Vdnw applied to the port of the deep N-well region is 0.9 V, and the third voltage Vbulk applied to the port of the P-well region is 1 V. When 1024 NMOSs are connected in series in the RRAM array and the width-to-length ratio of the NMOS is 270 μm/270 μm, simulation results are shown in FIG. 8.

As shown in FIG. 8, a curve M0 is a simulation curve of the transistor structure in the embodiments of the present disclosure, and a curve M1 is a simulation curve of the transistor structure in the related art. When drain voltage Vd=2.5 V is selected, the turn-on current Idsat of M0 is 35.7456 mA, and the turn-on current Idsat of M1 is 31.96 mA. It can be seen that after the deep N-well region is added, the transistor structure is easily turned on by applying a positive voltage to the P-well region, thereby reducing the threshold voltage of the transistor and increasing the turn-on current (Idsat) to enhance the turn-on characteristics of the device during normal turn-on.

In an embodiment, when the first operation is performed, the third voltage is greater than or equal to −1 V and less than 0 V; and when the second operation or the third operation is performed, the third voltage is greater than 0 V and less than or equal to 1 V.

An embodiment of the present disclosure further provides a memory apparatus, which includes:
a semiconductor device 100; where the semiconductor device 100 includes a substrate 10, a deep N-well region 11 disposed in the substrate 10, a P-well region 12 disposed in the deep N-well region 11, and a plurality of transistor structures disposed in the P-well region 12; where each of the transistor structures includes a gate 21, as well as a source 22 and a drain 23 disposed on two sides of the gate 21 respectively (see FIG. 5); and
a voltage module (not shown), configured to apply a first voltage to a port of the gate 21, apply a second voltage to a port of the deep N-well region 11, and apply a third voltage to a port of the P-well region 12.

When a first operation is performed, the first voltage is equal to 0, the second voltage is a positive voltage, and the third voltage is a negative voltage; and
when a second operation is performed, the first voltage is a positive voltage, the second voltage is a positive voltage, and the third voltage is a positive voltage.

In some embodiments, the substrate 10 may be an elemental semiconductor material substrate (such as a silicon substrate, a germanium substrate, or the like), a composite semiconductor material substrate (such as a germanium-silicon substrate, or the like), a silicon on insulator (SOI) substrate, a germanium on insulator (GeOI) substrate, or the like.

Then, the deep N-well region 11 is formed in the substrate 10, the P-well region 12 is formed in the deep N-well region 11, and the plurality of transistor structures are formed in the P-well region 12. The deep N-well region 11 isolates the substrate 10 from the P-well region 12 to control voltage in the P-well region separately.

In an embodiment, the transistor structure includes the gate 21, and the gate 21 includes a gate dielectric layer 211 disposed on the P-well region 12 and a gate conductive layer 212 disposed on the gate dielectric layer 211. The material of the gate dielectric layer 211 includes, but is not limited to oxides, such as silicon oxide. The material of the gate conductive layer 212 may be any material with good conductivity, such as any of titanium (Ti), titanium nitride (TiN), tungsten nitride (WN), tungsten (W), cobalt (Co), platinum (Pt), palladium (Pd), ruthenium (Ru), or copper (Cu).

The transistor structure further includes the source 22 and the drain 23 which are disposed on two sides of the gate 21. Specifically, as shown in FIG. 5, the source 22 and the drain 23 are disposed in the P-well region 12. In the embodiments of the present disclosure, the source 22 and the drain 23 are N-type doping regions.

In an embodiment, the semiconductor device 100 further includes: a resistive unit 40, a first end of the resistive unit 40 being connected to the drain 23 through a first connecting layer 31; a bit line BL connected to a second end of the resistive unit 40; a source line SL connected to the source 22 through a second connecting layer 32; and a word line WL connected to the gate 21.

Specifically, the first connecting layer 31 includes a first connecting line 311, a first conductive layer 312, and a second connecting line 313 arranged sequentially from bottom to top.

In an embodiment, the materials of the first connecting line 311 and the second connecting line 313 and the material of the first conductive layer 312 may include suitable conductor materials such as metal materials, barrier metal materials, or combinations thereof. The materials of the first connecting line 311 and the second connecting line 313 may be the same as or different from the material of the first conductive layer 312.

In an embodiment, the materials of the bit line BL, the source line SL, and the word line WL include tungsten (W), copper (Cu), titanium (Ti), tantalum (Ta), titanium nitride (TiN), tantalum nitride (TaN), metal silicide, metal alloy, or any combination thereof.

In an embodiment, the semiconductor device 100 further includes: a first doping region 51 disposed in the P-well region 12, a second doping region 52 disposed in the deep N-well region 11, and a third doping region 53 disposed in the substrate 10. The first doping region 51 is used for receiving voltage applied to the P-well region 12, the second doping region 52 is used for receiving voltage applied to the deep N-well region 11, and the third doping region 53 is used for receiving voltage applied to the substrate 10. The first doping region 51 is a P-type doping region, the second doping region 52 is an N-type doping region, and the third doping region 53 is a P-type doping region.

In an embodiment, when a third operation is performed, the first voltage is equal to 0, the second voltage is a positive voltage, and the third voltage is a positive voltage.

In the embodiments of the present disclosure, by giving a positive voltage to the P-well region, a reset circuit is turned on from the P-well region through a PN junction, without voltage division by transistors, but with easy operation and a high success rate. Additionally, all RRAMs share one P-well region to achieve chip-based reset, thereby reducing operation time.

In an embodiment, the second operation is a forming operation, and the third operation is a reset operation.

In an embodiment, the voltage module configured to apply the first voltage to the port of the gate 21 includes: the voltage module applies the first voltage to the port of the gate 21 through the word line WL.

The voltage module is further configured to apply a fourth voltage to the drain 23 through the bit line BL and ground the source 22 through the source line SL. The fourth voltage is a positive voltage.

As shown in FIG. 6, a port (PSUB) of the substrate 10 is also grounded.

In an embodiment, when the first operation is performed, the third voltage is greater than or equal to −1 V and less than 0 V; and when the second operation or the third operation is performed, the third voltage is greater than 0 V and less than or equal to 1 V.

According to embodiments of the present disclosure, the present disclosure further provides an electronic device and a readable storage medium.

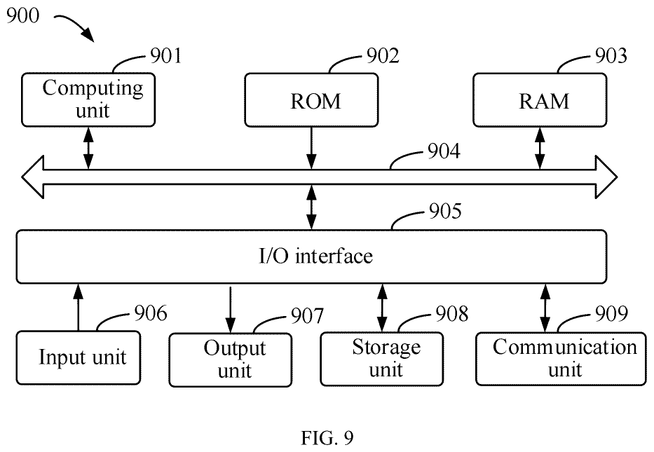

FIG. 9 illustrates a schematic block diagram of an exemplary electronic device 900 that can be used to implement the embodiments of the present disclosure. The electronic device is intended to represent various forms of digital computers, such as a laptop computer, a desktop computer, a workstation, a personal digital assistant, a server, a blade server, a mainframe computer, and other suitable computers. The electronic device may further represent various forms of mobile apparatuses, such as a personal digital assistant, a cellular phone, a smart phone, a wearable device, and other similar computing apparatuses. The components shown herein, their connections and relationships, and their functions are merely examples, and are not intended to limit the implementation of the present disclosure described and/or required herein.

As shown in FIG. 9, the device 900 includes a computing unit 901, which may perform various appropriate actions and processing according to a computer program stored in a read-only memory (ROM) 902 or a computer program loaded from a storage unit 908 to a random access memory (RAM) 903. The RAM 903 may further store various programs and data required for the operation of the device 900. The computing unit 901, the ROM 902, and the RAM 903 are connected to each other through a bus 904. An input/output (I/O) interface 905 is also connected to the bus 904.

A plurality of components in the device 900 are connected to the I/O interface 905, including: an input unit 906, such as a keyboard, a mouse and the like; an output unit 907, such as various types of displays, speakers and the like; a storage unit 908, such as a magnetic disk, an optical disk and the like; and a communication unit 909, such as a network card, a modem, a wireless communication transceiver and the like. The communication unit 909 allows the device 900 to exchange information/data with other devices over a computer network such as the Internet and/or various telecommunication networks.

The computing unit 901 may be various general-purpose and/or special-purpose processing components with processing and computing capabilities. Some examples of the computing unit 901 include, but are not limited to, a central processing unit (CPU), a graphics processing unit (GPU), various dedicated artificial intelligence (AI) computing chips, various computing units that run machine learning model algorithms, a digital signal processor (DSP), and any appropriate processor, controller, microcontroller and the like. The computing unit 901 performs various methods and processing described above, such as the method for operating a memory apparatus. For example, in some embodiments, the method for operating a memory apparatus can be implemented as a computer software program, which is tangibly included in a machine-readable medium, such as the storage unit 908. In some embodiments, a part or all of the computer program may be loaded and/or installed onto the device 900 via the ROM 902 and/or the communication unit 909. When the computer program is loaded onto the RAM 903 and executed by the computing unit 901, one or more steps of the method for operating a memory apparatus described above can be performed. Alternatively, in other embodiments, the computing unit 901 may be configured, by any other suitable means (for example, by means of firmware), to perform the method for operating a memory apparatus.

Various implementations of the systems and technologies described herein above can be implemented in a digital electronic circuit system, an integrated circuit system, a field programmable gate array (FPGA), an application-specific integrated circuit (ASIC), an application-specific standard product (ASSP), a system-on-chip (SOC) system, a complex programmable logical device (CPLD), computer hardware, firmware, software, and/or a combination thereof. The implementations may include: being implemented in one or more computer programs, the one or more computer programs may be executed and/or interpreted in a programmable system including at least one programmable processor, and the programmable processor may be a dedicated or general-purpose programmable processor, and may receive data and instructions from a storage system, at least one input apparatus, and at least one output apparatus, and transmit the data and instructions to the storage system, the at least one input apparatus, and the at least one output apparatus.

Program codes used to perform the method of the present disclosure can be written in any combination of one or more programming languages. These program codes may be provided for a processor or a controller of a general-purpose computer, a special-purpose computer, or other programmable data processing apparatuses, such that when the program codes are executed by the processor or the controller, the functions/operations specified in the flowcharts and/or block diagrams are implemented. The program codes may be completely executed on a machine, or partially executed on a machine, or may be, as an independent software package, partially executed on a machine and partially executed on a remote machine, or completely executed on a remote machine or a server.

In the context of the present disclosure, the machine-readable medium may be a tangible medium, which may include or store a program for use by an instruction execution system, apparatus or device, or for use in combination with the instruction execution system, apparatus or device. The machine-readable medium may be a machine-readable signal medium or a machine-readable storage medium. The machine-readable medium may include, but is not limited to, an electronic, magnetic, optical, electromagnetic, infrared, or semiconductor system, apparatus, or device, or any suitable combination thereof. More specific examples of the machine-readable storage medium may include an electrical connection based on one or more wires, a portable computer disk, a hard disk, a random access memory (RAM), a read-only memory (ROM), an erasable programmable read-only memory (EPROM or flash memory), an optical fiber, a portable compact disk read-only memory (CD-ROM), an optical storage device, a magnetic storage device, or any suitable combination thereof.

To provide interaction with a user, the systems and technologies described herein may be implemented in a computer, the computer is provided with: a display apparatus (such as a cathode ray tube (CRT) or a liquid crystal display (LCD) monitor) used for displaying information to the user; and a keyboard and a pointing apparatus (such as a mouse or a trackball), and the user may provide input to the computer through the keyboard and the pointing apparatus. Other types of apparatuses may also be used for providing interaction with the user; for example, feedback provided to the user may be sensory feedback in any form (such as visual feedback, auditory feedback, or tactile feedback); and the input of the user may be received in any form (including vocal input, speech input, or tactile input).

The systems and technologies described herein may be implemented in a computing system (for example, as a data server) including a background component, or a computing system (for example, an application server) including a middleware component, or a computing system (for example, a user computer with a graphical user interface or a web browser through which the user may interact with the implementation manners of the systems and technologies described herein) including a front-end component, or a computing system including any combination of the background component, the middleware component, or the front-end component. The components of the system may be connected with each other through digital data communication (for example, a communication network) in any form or medium. Examples of the communication network include: a local area network (LAN), a wide area network (WAN), and the Internet.

The computer system may include a client and a server. The client and the server are generally far away from each other and usually interact through the communications network. A relationship between the client and the server is generated by computer programs running in respective computers and having a client-server relationship with each other. The server may be a cloud server, a server in a distributed system, or a server combined with a blockchain.

It should be understood that the steps may be reordered, added or deleted by using the flows in various forms, which are shown above. For example, the steps recorded in the present disclosure may be performed concurrently, in order, or in a different order, provided that the desired results of the technical solutions disclosed in the present disclosure can be achieved, which is not limited herein.

In addition, the terms “first” and “second” are merely used for a description purpose, and cannot be interpreted as indicating or implying relative importance or implicitly indicating the number of the indicated technical features. Therefore, the features defined by “first” and “second” may explicitly or implicitly include at least one of the features. In the description of the present disclosure, “a plurality of” means two or more than two, unless otherwise specified.

What are described above are merely specific embodiments of the present disclosure, and are not intended to limit the scope of protection of the present disclosure, and any changes or substitutions that can readily occur to those skilled in the art within the scope of technologies disclosed in the present disclosure should fall within the scope of protection of the present disclosure. Therefore, the scope of protection of the present disclosure shall be subject to the scope of protection of the claims.

1. A method for operating a memory apparatus, comprising:
providing a semiconductor device, wherein the semiconductor device comprises a substrate, a deep N-well region disposed in the substrate, a P-well region disposed in the deep N-well region, and a plurality of transistor structures disposed in the P-well region; wherein each of the plurality of transistor structures comprises a gate, as well as a source and a drain disposed on two sides of the gate respectively; and
applying a first voltage to a port of the gate, applying a second voltage to a port of the deep N-well region, and applying a third voltage to a port of the P-well region;
wherein when a first operation is performed, the first voltage is equal to 0, the second voltage is a positive voltage, and the third voltage is a negative voltage;
when a second operation is performed, the first voltage is a positive voltage, the second voltage is a positive voltage, and the third voltage is a positive voltage.

2. The method according to claim 1, further comprising: when a third operation is performed, the first voltage is equal to 0, the second voltage is a positive voltage, and the third voltage is a positive voltage.

3. The method according to claim 2, wherein the second operation is a forming operation, and the third operation is a reset operation.

4. The method according to claim 1, wherein the semiconductor device further comprises: a resistive unit, a first end of the resistive unit being connected to the drain through a first connecting layer; a bit line connected to a second end of the resistive unit; a source line connected to the source through a second connecting layer; and a word line connected to the gate;
the step of applying the first voltage to the port of the gate comprises: applying the first voltage to the port of the gate through the word line;
the method further comprises:
applying a fourth voltage to the drain through the bit line; wherein the fourth voltage is a positive voltage; and
grounding the source through the source line.

5. The method according to claim 2, wherein
when the first operation is performed, the third voltage is greater than or equal to −1 V and less than 0 V; and
when the second operation or the third operation is performed, the third voltage is greater than 0 V and less than or equal to 1 V.

6. A memory apparatus, comprising:
a semiconductor device; wherein the semiconductor device comprises a substrate, a deep N-well region disposed in the substrate, a P-well region disposed in the deep N-well region, and a plurality of transistor structures disposed in the P-well region; wherein each of the plurality of transistor structures comprises a gate, as well as a source and a drain disposed on two sides of the gate respectively; and
a voltage module, configured to apply a first voltage to a port of the gate, apply a second voltage to a port of the deep N-well region, and apply a third voltage to a port of the P-well region;
wherein when a first operation is performed, the first voltage is equal to 0, the second voltage is a positive voltage, and the third voltage is a negative voltage;
when a second operation is performed, the first voltage is a positive voltage, the second voltage is a positive voltage, and the third voltage is a positive voltage.

7. The memory apparatus according to claim 6, wherein when a third operation is performed, the first voltage is equal to 0, the second voltage is a positive voltage, and the third voltage is a positive voltage.

8. The memory apparatus according to claim 7, wherein the second operation is a forming operation, and the third operation is a reset operation.

9. The memory apparatus according to claim 6, wherein the semiconductor device further comprises: a resistive unit, a first end of the resistive unit being connected to the drain through a first connecting layer; a bit line connected to a second end of the resistive unit; a source line connected to the source through a second connecting layer; and a word line connected to the gate;
the voltage module is further configured to apply the first voltage to the port of the gate through the word line; and
the voltage module is further configured to:
apply a fourth voltage to the drain through the bit line; wherein the fourth voltage is a positive voltage; and
ground the source through the source line.

10. The memory apparatus according to claim 7, wherein
when the first operation is performed, the third voltage is greater than or equal to −1 V and less than 0 V; and
when the second operation or the third operation is performed, the third voltage is greater than 0 V and less than or equal to 1 V.

11. An electronic device, comprising:
at least one processor; and
a memory in communication connection with the at least one processor;
wherein the memory stores instructions executable by the at least one processor, and the instructions are executed by the at least one processor to cause the at least one processor to execute the method according to claim 1.

12. A non-transitory computer-readable storage medium storing computer instructions, wherein the computer instructions are executed by a computer to cause the computer to perform the method according to claim 1.
